(19) United States
(12) Patent Application Publication
(10) Pub. No.: US 2009/0085120 A1
(43) Pub. Date: Apr. 2, 2009

(54) Method for Reduction of Resist Poisoning in Via-First Trench-Last Dual Damascene Process

(75) Inventors: Zhijian Lu, Boxborough, MA (US); Tae S. Kim, Dallas, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/863,448

(22) Filed: Sep. 28, 2007

(51) Int. Cl. H01L 21/768; H01L 21/8234; H01L 27/088

(52) U.S. Cl. 257/368; 438/618; 438/275; 257/E21.627; 257/E21.575; 257/E27.06

(57) ABSTRACT

Fabrication of interconnects in integrated circuits (ICs) use low-k dielectric materials, nitrogen containing dielectric materials, copper metal lines, dual damascene processing and amplified photoresists to build features smaller than 100 nm. Regions of an IC with low via density are subject to nitrogen diffusion from nitrogen containing dielectric materials into low-k dielectric material, and subsequent interference with forming patterns in amplified photoresists, a phenomenon known as resist poisoning, which results in defective interconnects. Attempts to solve this problem cause lower IC circuit performance or higher fabrication process cost and complexity. This invention comprises a dummy via and a method of placing dummy vias in a manner that reduces resist poisoning without impairing circuit performance or increasing fabrication process cost or complexity.

### FIELD OF THE INVENTION

This invention relates to the field of integrated circuits. More particularly, this invention relates to interconnect design and fabrication of integrated circuits using dual damascene copper interconnects with low-k dielectrics.

### BACKGROUND OF THE INVENTION

It is well known that integrated circuits (ICs) consist of electrical components such as transistors, diodes, resistors and capacitors built into the top layer of a semiconductor wafer, typically a silicon wafer. It is also well known that these components are connected to form useful circuits by metal interconnects consisting of several alternating layers of vertical metal vias and horizontal metal lines, separated by dielectric materials. Copper metal is used to form interconnects. Additionally, dielectric materials with lower dielectric constants than silicon dioxide, such as organo-silicate glass, collectively known as “low-k dielectrics,” are used to separate the copper interconnects Low-k dielectric materials achieve their low dielectric constants (relative to silicon dioxide) in two ways. The first is substitution of lighter elements for silicon and oxygen. The second is increased porosity (voids have a dielectric constant lower than bulk dielectric material). Most low-k dielectric materials utilize a combination of these two methods. In addition to low-k dielectrics, layers of nitrogen containing films, such as silicon nitride and silicon carbide nitride, are used for dielectric etch stop layers, dielectric etch hard mask layers and CMP stop layers, as well as other functions. Nitrogen from these films can diffuse into the low-k dielectric material.

The procedure for forming interconnects is known as dual damascene processing. Dual damascene processing involves fabricating a level of vertical metal vias and a level of horizontal metal lines above the vias, in one process sequence. A commonly used sequence of fabrication steps is known as the via-first sequence. In via-first processing, holes for vertical metal vias on one level are defined using known photolithographic techniques and etched into low-k dielectric material using known etching techniques. Following via etch, trenches for the corresponding horizontal metal lines are defined using similar photolithographic techniques and etched into low-k dielectric material using similar etch techniques. Photoresists used for defining interconnects are very sensitive to contaminants such as nitrogen containing molecules, which disrupt the photochemical process in the photoresist by which via and trench patterns are generated. A source of nitrogen containing contaminant molecules is the nitrogen containing films used in the interconnect dielectric for etch stops and hard masks, as discussed above. Diffusion of nitrogen containing molecules from nitrogen containing etch stop layers and hard mask layers into the low-k dielectric material, and subsequently into photoresist used for generating trench patters after via holes have been etched causes problems in the trench pattern photolithography operation. Via holes allow significant absorption of nitrogen containing molecules from low-k dielectric material into photoresist, which results in poorly defined trench patterns in areas close to vias. This phenomenon is known as resist poisoning. Regions with low via density exhibit worse resist poisoning, because more contaminant is absorbed per via in low via density regions.

Methods to reduce resist poisoning include employing blocking layers of dielectric materials in etch stop and hard mask layers that reduce the diffusion of nitrogen containing contaminants into low-k dielectric materials, but resist poisoning remains a serious problem in IC fabrication, reducing yield and increasing manufacturing costs. In addition, this attempted remedy has a disadvantage of adding capacitance to interconnects, which degrades circuit performance. Another attempted remedy is to treat low-k dielectric materials with plasma processes to reduce diffusibility of amine molecules. This attempted remedy has a disadvantage of adding process complexity and cost. Since this process must be repeated for several interconnect levels, cost and complexity penalties are increased.

### SUMMARY OF THE INVENTION

This summary is provided to comply with 37 C.F.R. §1.73, requiring a summary of the invention briefly indicating the and substance of the invention. It is submitted with the understanding that it will not be used to interpret or limit the scope or meaning of the claims.

This invention consists of a dummy via to prevent resist poisoning, and a method of forming same. Dummy vias arc vertical metal vias which are formed in an integrated circuit (IC) to improve the fabrication process, but are not functional to the circuits in the IC. In regions of an IC that utilize dummy metal, an embodiment of this invention comprises formation of dummy vias in the dummy metal overlap regions. Another embodiment of this invention comprises formation of dummy metal structures and dummy vias. In another embodiment of this invention, dummy vias may be formed between circuit interconnect elements and dummy metal elements. Another embodiment of this invention comprises formation of redundant vias in circuit interconnect elements.

### DESCRIPTION OF THE VIEWS OF THE DRAWING

FIG. 1 depicts a cross-section of an integrated circuit (IC) during a dual damascene process sequence, including an embodiment of the instant invention.

FIG. 2 is a top view of a portion of interconnects of an IC, providing circuit interconnects and dummy metal pads, including an embodiment of the instant invention.

FIG. 3 is a top view of a portion of interconnects of an IC, including an embodiment of the instant invention.

FIG. 4 is a top view of a portion of interconnects of an IC, including an embodiment of the instant invention.

FIG. 5 is a top view of a portion of interconnects of an IC, including an embodiments of the instant invention.

### DETAILED DESCRIPTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

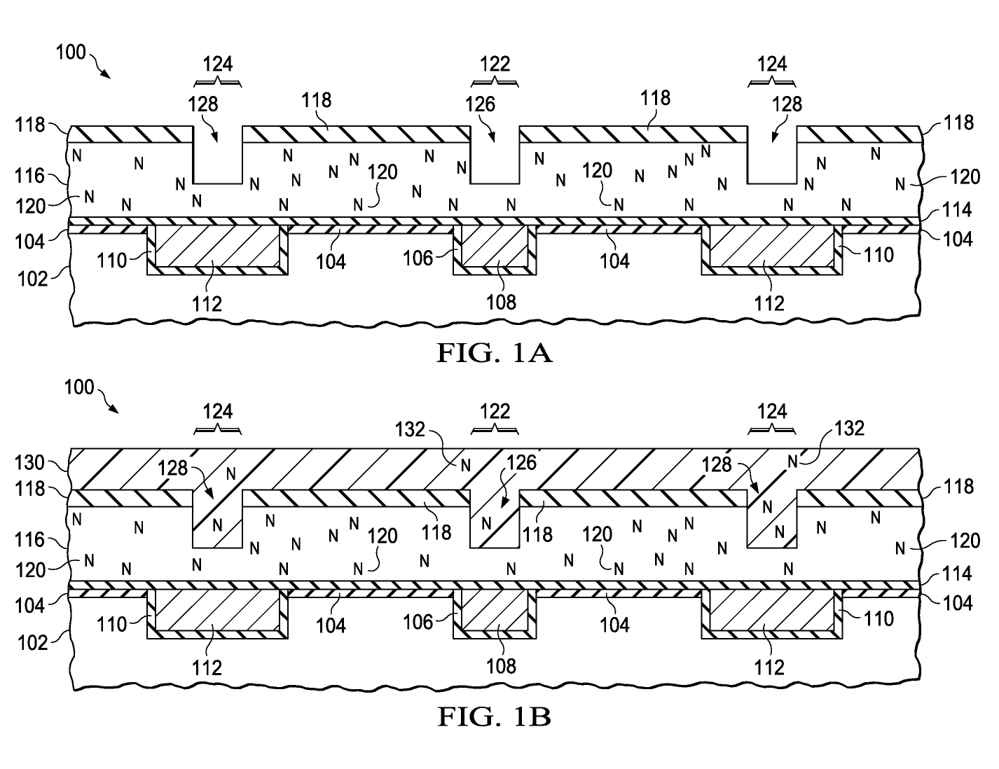

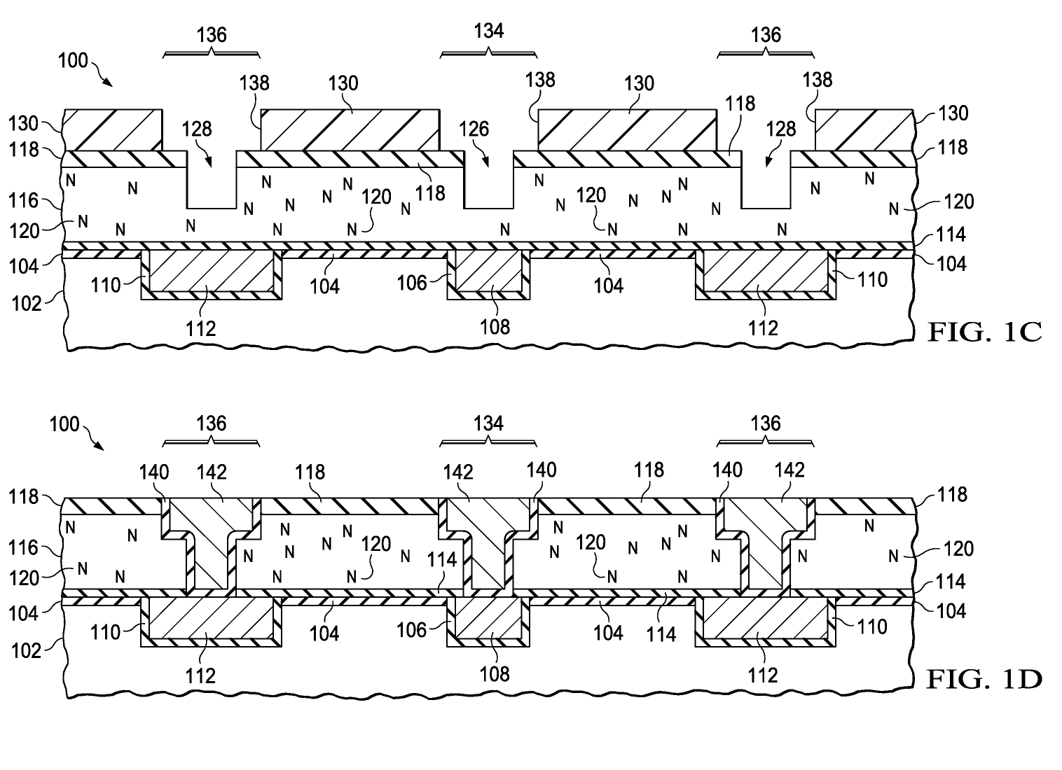

FIG. 1 depicts a cross-section of an integrated circuit (IC) during a dual damascene process sequence. FIG. 1A depicts the IC after via holes have been etched. IC (100) contains a first inter-level dielectric (ILD) (102), typically low-k dielectric material, and optional cap layer (104), typically silicon dioxide, silicon nitride, silicon carbide nitride, silicon carbide oxide, or silicon carbide. A first functional interconnect structure is formed in the first ILD (102), made of a first liner metal (106) and a first fill metal (108), typically copper. Liner metal and fill metal are deposited and selectively removed to form one level of interconnects, typically by chemical-mechanical polish (CMP). The CMP process uniformity and repeatability are sensitive to the fraction of IC surface area defined for interconnect structures at each level, in regions from 10 to 100 microns in size. Since current IC designs vary widely in metal density, small islands of metal are formed in open areas on each interconnect level, where possible, to reduce the number and size of regions with low metal density. These islands of metal are commonly referred to as dummy metal, and they are not electrically connected to circuit components in the IC circuits, that is, they are separated from all circuit components in the IC by dielectric materials. In addition to functional interconnects in the first ILD (102), a first set of dummy metal structures are formed in the first ILD (102), made of a second liner metal (110) and a second fill metal (112) in the first ILD (102). A typical dual damascene process sequence begins with deposition of a via etch stop layer (114), typically silicon nitride or silicon carbide nitride, on the first ILD (102), followed by deposition of a second ILD layer (116), typically low-k dielectric material, followed by deposition of a hard mask layer (118), typically silicon nitride or silicon carbide nitride. During subsequent processing, nitrogen from the via etch stop layer (114) and from the hard mask (118) may diffuse into the second ILD layer (116) and reside as a mobile nitrogen species (120).

Still referring to FIG. 1A, the dual damascene process sequence continues with photolithographically defining functional via regions (122). In a first embodiment of the instant invention, dummy via regions (124) are defined in the same photolithographic operation. In the functional via regions (122) and dummy via regions (124), hard mask layer (118) and second ILD layer (116) is removed by known etch techniques, forming functional via holes (126) and dummy via holes (128).

A next operation in dual damascene processing is deposition of photoresist for definition of a set of second metal interconnect regions. FIG. 1B depicts the IC after deposition of the photoresist (130). Mobile nitrogen species (120) in the second ILD layer (116) may diffuse into the photoresist (130) by way of the via holes (126, 128), forming nitrogen containing species (132) in the photoresist (130). The dummy via holes (128) are advantageous because they distribute the nitrogen containing species (132) more uniformly in the photoresist (130), preventing regions of local concentration that interfere with proper photochemical processes in the photoresist (130) during exposure and development.

The dual damascene process sequence proceeds with definition of a set of second functional metal interconnect regions (134) and a set of second dummy metal regions (136), known as the trench pattern, in the photoresist (130). The trench pattern (138) in the photoresist (130) has correct dimensions and essentially vertical profiles, because the dummy via holes (128) distributed the nitrogen containing species more uniformly in the photoresist, as explained above.

Dual damascene processing continues with etching the hard mask layer (118) and second ILD layer (116) in the second functional interconnect regions (134) and second dummy metal regions (136), proceeds further with deposition of a third liner metal (140) and third fill metal (142), typically copper, on the hard mask layer (118) and in the trench and via holes, and concludes with selective removal of the third liner metal (140) and third fill metal (142) from a top surface of the hard mask layer (118), typically by CMP, thus forming a first set of vias and a second set of horizontal interconnect structures, leaving a top surface of the third fill metal (142) level with the top surface of the hard mask layer (118), as depicted in FIG. 1D.

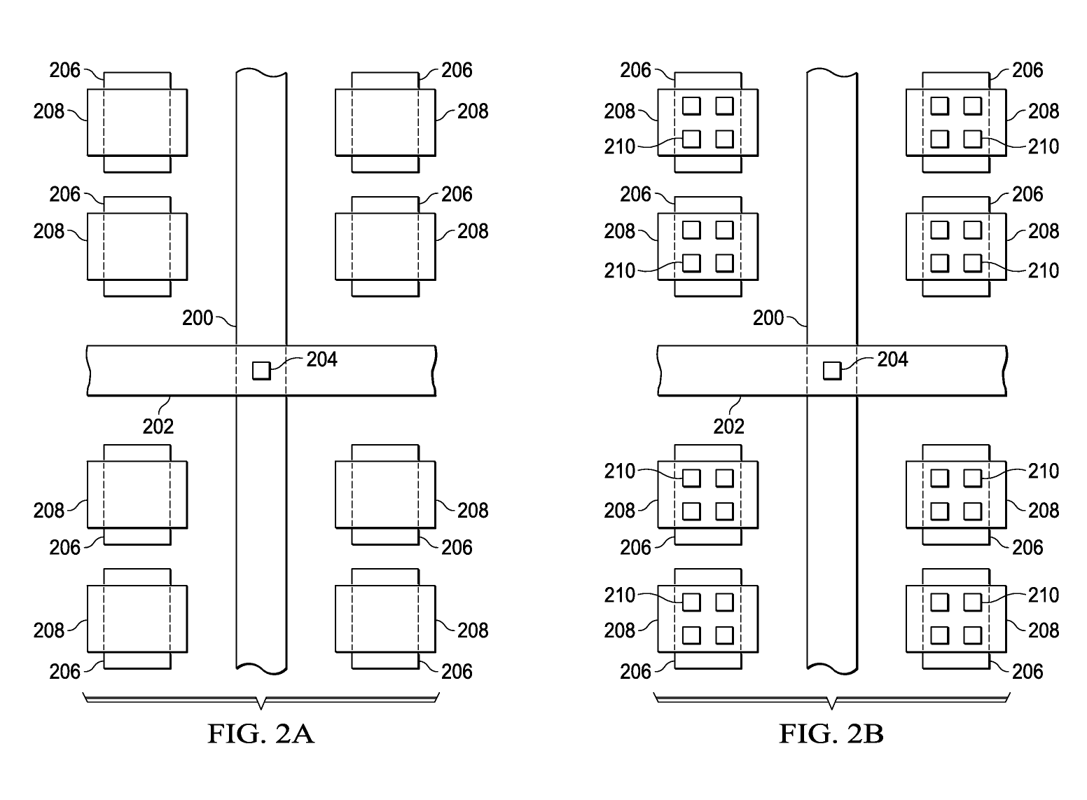

FIG. 2 is a top view of a portion of interconnects of an IC, providing circuit interconnects and dummy metal pads. FIG. 2A depicts a portion of the interconnects of the IC before implementation of an embodiment of the instant invention, and FIG. 2B depicts the portion of the interconnects of the IC after implementation of an embodiment of the instant invention. In FIG. 2A, a first horizontal interconnect line (200) is electrically connected to a second horizontal interconnect line (202) by a via (204); all three elements (200, 202, 204) are functional to the integrated circuit. A first set of dummy metal pads (206), on the same interconnect level as the first horizontal interconnect line (200), and a second set of dummy metal pads (208), on the same interconnect as the second horizontal interconnect line (202), have been provided to improve the uniformity of the CMP processes, as discussed above. Furthermore, overlap regions exist between the first set of dummy metal pads (206) and the second set of dummy metal pads (208). The via density in the interconnect region depicted in FIG. 2A is very low.

In an embodiment of this invention, depicted in FIG. 2B, dummy vias (210) are placed in areas of overlap between the first set of dummy metal pads and the second set of dummy metal pads.

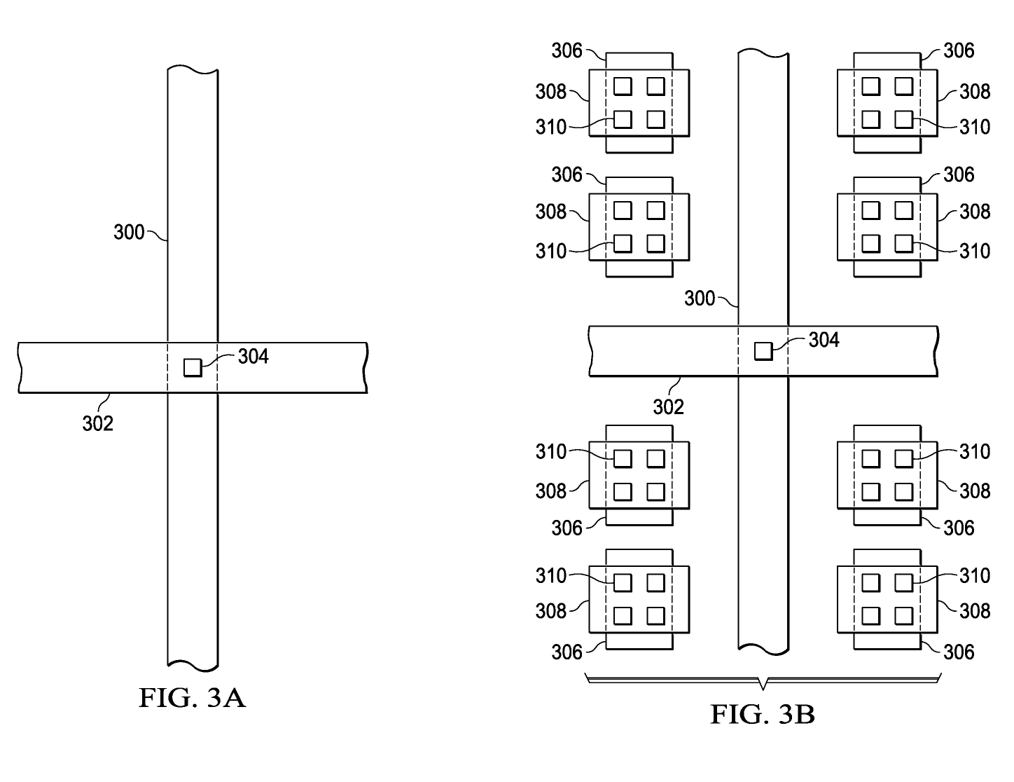

FIG. 3 is a top view of a portion of interconnects of an IC, providing circuit interconnects. FIG. 3A depicts a portion of the interconnects of the IC before implementation of an embodiment of the instant invention, and FIG. 3B depicts the portion of the interconnects of the IC after implementation of an embodiment of the instant invention. In FIG. 3A, a first horizontal interconnect line (300) is electrically connected to a second horizontal interconnect line (302) by a via (304); all three elements (300, 302, 304) are functional to the integrated circuit. The via density in the interconnect region depicted in FIG. 3A is very low.

In an embodiment of this invention, depicted in FIG. 3B, a first set of dummy metal pads (306), on the same interconnect level as the first horizontal interconnect line (300), and a second set of dummy metal pads (308), on the same interconnect as the second horizontal interconnect line (302), wherein overlap regions exist between the first set of dummy metal pads (306) and the second set of dummy metal pads (308), and dummy vias (310) are placed in the areas of overlap between the first set of dummy metal pads and the second set of dummy metal pads.

In another embodiment of this invention, which may be used in regions wherein dummy metal pads are provided on one level of interconnect, but not on an adjacent level, dummy metal pads may be formed in the interconnect level lacking said dummy metal pads, and dummy vias may be formed, whereby the dummy vias connect the dummy metal pads on the two interconnect levels.

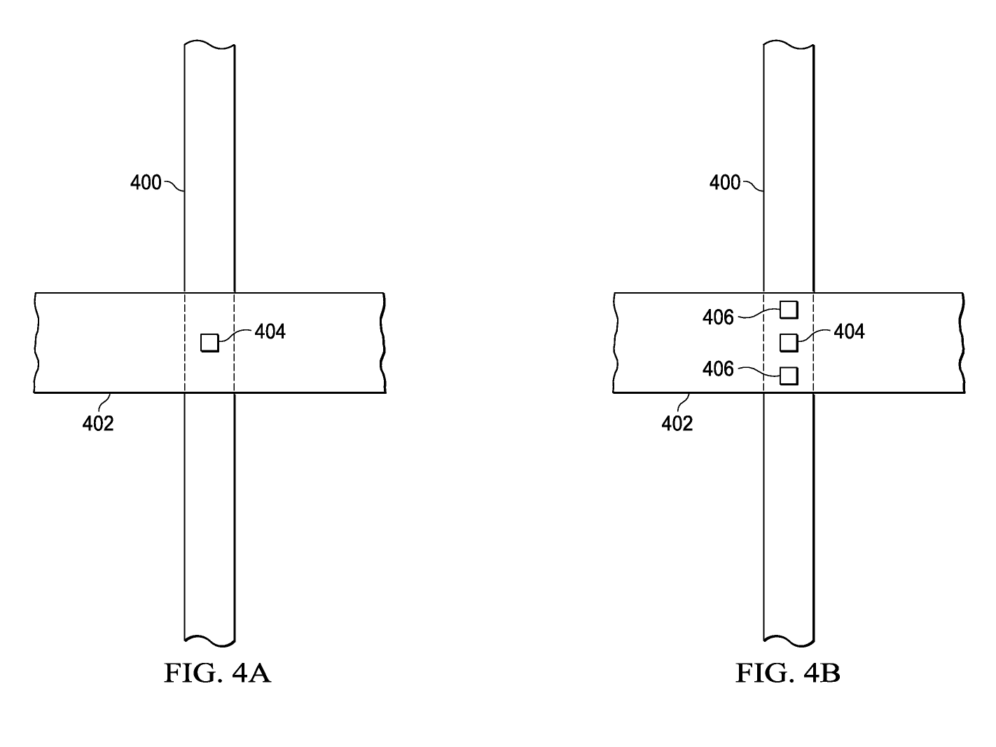

Another embodiment of the instant invention is illustrated in FIG. 4, which depicts a top view of a portion of interconnects of an IC, providing circuit interconnects. FIG. 4A depicts a portion of the interconnects of the IC before implementation of an embodiment of the instant invention, and FIG. 4B depicts the portion of the interconnects of the IC after implementation of an embodiment of the instant invention. In FIG. 4A, a first horizontal interconnect line (400) is electrically connected to a second horizontal interconnect line (402) by a via (404); all three elements are functional to the integrated circuit. The via density in the interconnect region depicted in FIG. 4A is very low.

In an embodiment of this invention, depicted in FIG. 4B, redundant vias (406) are formed in the overlap region of the first horizontal interconnect line (400) and the second horizontal interconnect line (402), reducing the risk of resist poisoning affecting a photoresist pattern for the second horizontal interconnect line (402).

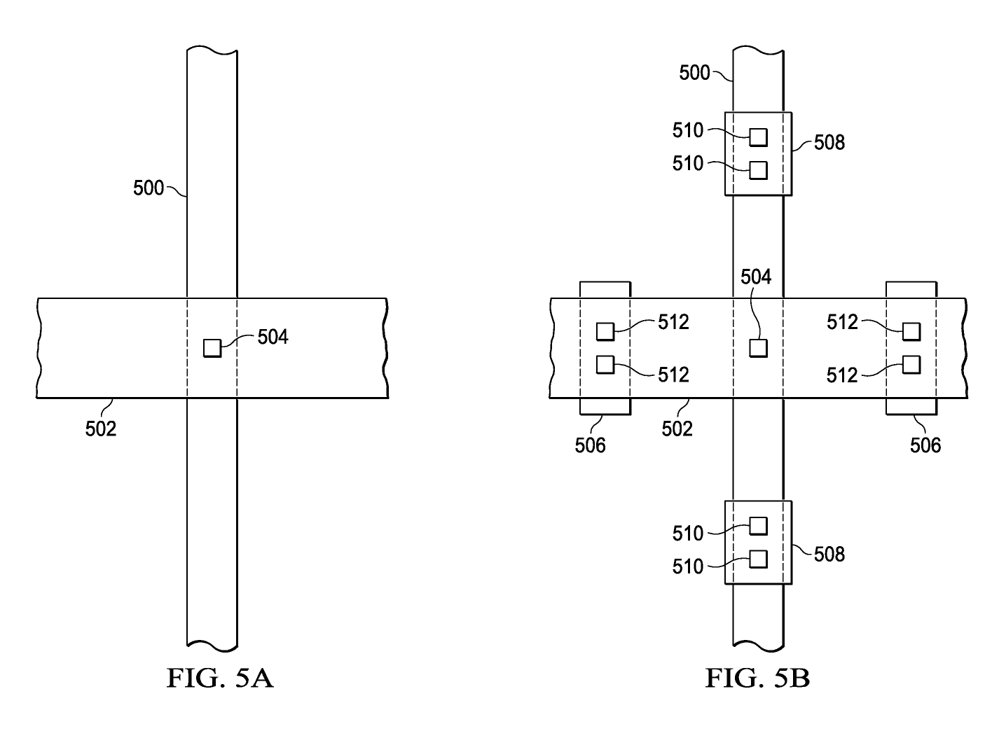

Another embodiment of the instant invention is illustrated in FIG. 5, which depicts a top view of a portion of interconnects of an IC, providing circuit interconnects. FIG. 5A depicts a portion of the interconnects of the IC before implementation of an embodiment of the instant invention, and FIG. 5B depicts the portion of the interconnects of the IC after implementation of an embodiment of the instant invention. In FIG. 5A, a first horizontal interconnect line (500) is electrically connected to a second horizontal interconnect line (502) by a via (504); all three elements are functional to the integrated circuit. The via density in the interconnect region depicted in FIG. 5A is very low.

In an embodiment of this invention, depicted in FIG. 5B, dummy metal elements (506) are formed on the same interconnect level as the first horizontal interconnect line (500), to provide overlap regions with the second horizontal interconnect line (502), capable of supporting dummy vias. Similarly, dummy metal elements (508) are formed on the same interconnect level as the second horizontal interconnect line (502), to provide overlap regions with the first horizontal interconnect line (500), capable of supporting dummy vias. Dummy vias (510) are formed in the overlap regions between the second horizontal interconnect line (502) and the dummy metal elements (506), and dummy vias (512) are formed in the overlap regions between the first horizontal interconnect line (500) and the dummy metal elements (508), reducing the risk of resist poisoning affecting photoresist patterns for the first and second horizontal interconnect lines (500, 502).

It will be apparent to practitioners of interconnect fabrication that the embodiments discussed above may be extended to all levels of interconnects for a given IC. For example, in an IC with seven levels of horizontal interconnects, dummy vias embodying the instant invention may be used on the via 1 level, via 2 level, and so on through the via 6 level. It will be further apparent practitioners of interconnect fabrication that dummy metal pads may be modified in size, shape and location, in any combination, to create or extend overlap regions for the purpose of forming dummy vias.

It will also be apparent to practitioners of interconnect fabrication that several different embodiments of the instant invention may be used on an IC. For example, if dummy metal pads exist on metal level 1 and metal level 2 in a region of the integrated circuit and overlap each other sufficiently to allow the placement of dummy vias, the embodiment consisting of forming dummy vias may be used. In another region of the IC, if no dummy metal pads exist, the embodiment consisting of forming dummy metal pads to two sequential levels of interconnect and forming dummy vias to connect the dummy metal pads may be used.

A density of dummy vias required to reduce effects of resist poisoning on IC performance will depend on details of an instant interconnect fabrication process and operating characteristics of the IC. A via density of one via per 100 square microns of surface area at each level of interconnect will suffice for less sensitive applications. A via density of one via per 2 square microns of surface area at each level of interconnect may be necessary to maintain unimpeded circuit performance for ICs built using 65 nm technology node design rules.

What is claimed is:

1. A method of fabricating dummy vias in an integrated circuit, comprising the steps of:
providing a substrate;
forming electronic components in said substrate;
forming a first set of interconnect structures over said electronic components;
forming vias on said first set of interconnect structures, whereby the vias contact said first set of interconnect structures; and
forming a second set of interconnect structures whereby the second set of interconnect structures contact and overlap said vias on said first set of interconnect structures.

2. The method of claim 1, wherein said vias comprise a metal liner and a fill metal.

3. The method of claim 1, wherein said first set of interconnect structures are not electrically connected to said electronic components in said substrate.

4. The method of claim 1, wherein said second set of interconnect structures are not electrically connected to said electronic components in said integrated circuit.

5. The method of claims 1, whereby the step of forming vias on said first set of interconnect structures raises the density of vias in any region of said integrated circuit more than 100 microns wide and 100 microns long to a value greater than 1 via per 100 square microns.

6. The method of claims 1, 2 or 3, whereby the step of forming metal vias on said first set of interconnect structures raises the density of metal vias in any region of said integrated circuit more than 100 microns wide and 100 microns long to a value greater than 1 via per 2 square microns.

7. A method of forming an integrated circuit, comprising the steps of providing a substrate;
forming field oxide in said substrate;
forming an n-well in said substrate;
forming a p-well in said substrate;
forming an n-channel MOS transistor in said p-well by a process comprising the steps of:
forming a first gate dielectric on a top surface of said p-well;
forming a first gate structure on a top surface of said first gate dielectric;
forming n-type source and drain regions in said p-well adjacent to said first gate structure and contacting said n-type lightly doped source and drain regions; and
forming a first set of silicide regions on, and in contact with, top surfaces of said n-type source and drain regions;
forming a p-channel MOS transistor in said n-well by a process comprising the steps of:
forming a second gate dielectric on a top surface of said n-well;
forming a second gate structure on a top surface of said second gate dielectric;
forming p-type source and drain regions in said n-well adjacent to said second gate structure and contacting said p-type lightly doped source and drain regions; and
forming a second set of silicide regions on, and in contact with, top surfaces of said p-type source and drain regions;
forming a pre-metal dielectric layer stack on said n-channel transistor and said p-channel transistor;
forming contacts in said pre-metal dielectric layer stack on, and electrically connected to, said n-type source and drain regions and said p-type source and drain regions;
forming a first intra-metal dielectric layer on said pre-metal dielectric layer stack;
forming a first set of interconnect structures in said first intra-metal dielectric layer;
forming a first inter-level dielectric layer on said first set of interconnect structures;
forming vias in said first inter-level dielectric layer, whereby the metal vias contact said first set of interconnect structures; and
forming a second set of interconnect structures in said first inter-level dielectric layer, whereby the second set of interconnect structures contact and overlap said vias.

8. The method of claim 7, wherein said first set of interconnect structures are not electrically connected to said n-channel MOS transistor or said p-channel MOS transistor.

9. The method of claim 7, wherein said second set of interconnect structures are not electrically connected to said n-channel MOS transistor or said p-channel MOS transistor.

10. The method of claims 7, whereby the step of forming vias in said first inter-level dielectric layer raises the density of vias in any region of said integrated circuit more than 100 microns wide and 100 microns long to a value greater than 1 via per 100 square microns.

11. The method of claims 7, whereby the step of forming vias in said first inter-level dielectric layer raises the density of vias in any region of said integrated circuit more than 100 microns wide and 100 microns long to a value greater than 1 via per 2 square microns.

12. An integrated circuit, comprising:
provided a substrate;
a region of field oxide in said substrate;
an n-well in said substrate;
a p-well in said substrate;
an n-channel MOS transistor in said p-well comprising:
a first gate dielectric on a top surface of said p-well;
a first gate structure on a top surface of said first gate dielectric;
n-type source and drain regions in said p-well adjacent to said first gate structure; and
a first set of silicide regions on, and in contact with, top surfaces of said n-type source and drain regions;
a p-channel MOS transistor in said n-well comprising:
a second gate dielectric on a top surface of said n-well;
a second gate structure on a top surface of said second gate dielectric;
p-type source and drain regions in said n-well adjacent to said second gate structure; and
a second set of silicide regions on, and in contact with, top surfaces of said p-type source and drain regions;
a pre-metal dielectric layer stack on said n-channel transistor and said p-channel transistor;
contacts in said pre-metal dielectric layer stack on, and electrically connected to, said n-type source and drain regions and said p-type source and drain regions;
a first intra-metal dielectric layer on said pre-metal dielectric layer stack;
a first set of interconnect structures in said first intra-metal dielectric layer;
a first inter-level dielectric layer on said first set of interconnect structures;
vias in said first inter-level dielectric layer, whereby the vias contact said first set of interconnect structures; and
a second set of interconnect structures in said first inter-level dielectric layer, whereby the second set of interconnect structures contact and overlap said vias.

13. The integrated circuit of claim 12, wherein said first set of interconnect structures are not electrically connected to said n-channel MOS transistor or said p-channel MOS transistor.

14. The integrated circuit of claim 12, wherein said second set of interconnect structures are not electrically connected to said n-channel MOS transistor or said p-channel MOS transistor.

15. The integrated circuit of claim 12, wherein said vias in said first inter-level dielectric layer have a density greater than 1 via per 100 square microns, in any region of the integrated circuit more than 100 microns wide and 100 microns long.

16. The integrated circuit of claim 12, wherein said vias in said first inter-level dielectric layer have a density greater than 1 via per 2 square microns, in any region of the integrated circuit more than 100 microns wide and 100 microns long.
